(19) United States
(12) Patent Application Publication
(10) Pub. No.: US 2021/0095377 A1
(43) Pub. Date: Apr. 1, 2021

(54) SUBSTRATE HEATING SYSTEM AND SUBSTRATE PROCESSING DEVICE

(71) Applicant: NISSIN ELECTRIC CO., LTD., Kyoto (JP)

(72) Inventors: Tsubasa IWAKOKE, Kyoto (JP); Yumi YANAI, Kyoto (JP)

(73) Assignee: NISSIN ELECTRIC CO., LTD., Kyoto (JP)

(21) Appl. No.: 16/982,046

(22) PCT Filed: Mar. 19, 2018
(86) PCT No.: PCT/JP2018/010821

§ 371 Date: Sep. 18, 2020

(51) Int. Cl. C23C 16/46; C23C 14/54; C23C 14/50; C23C 16/52; C23C 16/458; C23C 14/34

(52) U.S. Cl. CPC C23C 16/46; C23C 14/541; C23C 14/34; C23C 16/52; C23C 16/4585; C23C 14/50

(57) ABSTRACT

The present invention provides a substrate heating system and a substrate processing device. The substrate heating system comprises: a top plate on which a substrate is mounted; a heater that is provided to a lower surface of the top plate; a plate temperature detection part that detects the temperature of the top plate; a heater temperature detection part that detects the temperature of the heater; and a heater control part that controls the output of the heater on the basis of the detected temperature of the heater and the detected temperature of the top plate. The heater control part controls the output of the heater such that a detected temperature difference between the detected temperature of the heater and the detected temperature of the top plate does not exceed a prescribed temperature difference upper limit and such that the detected temperature of the top plate is a prescribed set temperature.

### BACKGROUND

### Technical Field

The present invention relates to a substrate heating system and a substrate processing device.

### Description of Related Art

In related art, there is a substrate heating control system shown in Patent Document 1 as a system for heating a substrate on which substrate processing such as film formation is performed.

This substrate heating control system detects a temperature of a top plate on which a substrate is placed, performs control in a plurality of temperature management modes prepared in advance (in which a set temperature of a heater is changed over time) when the detected temperature of the top plate is lower than a prescribed threshold, and performs PID control when the temperature of the top plate is higher than the prescribed threshold.

However, when a temperature of the heater is set to be high at the start of temperature rise, a temperature difference between the top plate and the heater increases, and there is concern of the heater being damaged due to a difference in thermal expansion between the top plate and the heater.

### CITATION LIST

### Patent Literature

[Patent Literature 1]: Japanese Patent No. 3810726

### SUMMARY

### Technical Problem

Therefore, the present invention has been made to solve the above problem, and a main objective of the present invention is to reduce disparity of thermal expansion between a top plate and a heater and prevent damage to the heater.

### Solution to Problem

That is, the substrate heating system according to the present invention includes a top plate on which a substrate is placed; a heater provided to a lower surface of the top plate; a plate temperature detection part configured to detect a temperature of the top plate; a heater temperature detection part configured to detect a temperature of the heater; and a heater control part configured to control an output of the heater based on the detected temperature of the heater and the detected temperature of the top plate, wherein the heater control part controls the output of the heater such that a detected temperature difference between the detected temperature of the heater and the detected temperature of the top plate does not exceed a prescribed temperature difference upper limit value and performs control such that the detected temperature of the top plate is a prescribed set temperature.

According to the present invention as described above, since the output of the heater is controlled such that the detected temperature difference between the detected temperature of the heater and the detected temperature of the top plate does not exceed the prescribed temperature difference upper limit value, it is possible to reduce disparity in thermal expansion between the top plate and the heater and prevent damage to the heater.

Specifically, it is preferable for the heater control part to set an output upper limit value of the heater based on the detected temperature difference. With this configuration, it is possible to cause the detected temperature of the top plate to rise toward the set temperature and prevent the detected temperature difference between the detected temperature of the heater and the detected temperature of the top plate from exceeding the temperature difference upper limit value.

Specifically, it is preferable for the heater control part to subtract a prescribed value from a current output upper limit value and set a resultant value to a next output upper limit value when the detected temperature difference is larger than a prescribed target temperature difference value, and to add a prescribed value to the current output upper limit value and set a resultant value as the next output upper limit value when the detected temperature difference is smaller than the prescribed target temperature difference value.

In a case in which the detected temperature difference is smaller than the prescribed target temperature difference value, it is preferable for the heater control part to add a prescribed value to the current output upper limit value and set a resultant value as the next output upper limit value when a difference between the target temperature difference value and the detected temperature difference is larger than a prescribed threshold, and not to change the current output upper limit value when the difference between the target temperature difference value and the detected temperature difference is smaller than the prescribed threshold. With this configuration, it is possible to prevent the detected temperature difference between the detected temperature of the heater and the detected temperature of the top plate from exceeding the temperature difference upper limit value in consideration of a delay in response of temperature control.

It is preferable for the heater control part to switch the target temperature difference value based on a detected temperature of the top plate. It is possible to shorten a temperature rise time of the top plate by performing switching such that the target temperature difference value gradually increases when the detected temperature of the top plate rises, for example.

As a specific control aspect of the heater control part, it is preferable for the heater control part to control the output of the heater such that the detected temperature difference does not exceed the temperature difference upper limit value when the detected temperature of the top plate is lower than a threshold temperature obtained by subtracting a prescribed temperature from the set temperature, and to perform control such that the detected temperature of the top plate is the set temperature when the detected temperature of the top plate is higher than the threshold temperature.

It is preferable for the heater control part to control the output of the heater using a prescribed first output upper limit value when the detected temperature of the heater exceeds a prescribed heater temperature upper limit value.

It is preferable for the heater control part to control the output of the heater using a prescribed second output upper limit value when the detected temperature difference exceeds the temperature difference upper limit value.

### Advantageous Effects of Invention

According to the present invention having such a configuration, it is possible to reduce disparity in thermal expansion between the top plate and the heater and prevent damage to the heater.

### BRIEF DESCRIPTION OF THE DRAWINGS

FIG. 1 is a schematic diagram illustrating a configuration of a substrate heating system according to the present embodiment.

FIG. 2 is a flowchart from power-on of a heater to completion of temperature rise in the embodiment.

FIG. 3 is a flowchart illustrating a process of calculating an output upper limit value in the embodiment.

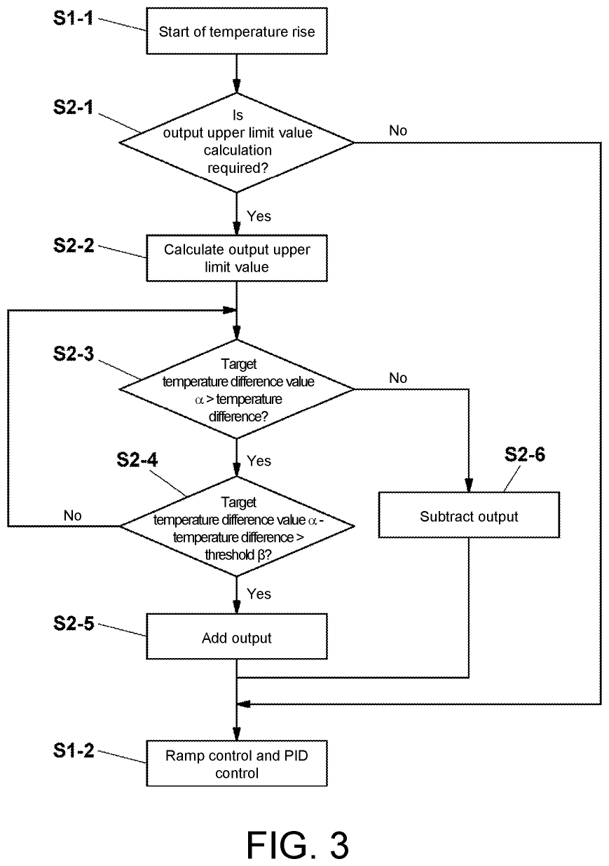

FIG. 4 is a graph illustrating a time series relationship between a set temperature and a detected temperature of a top plate in the embodiment.

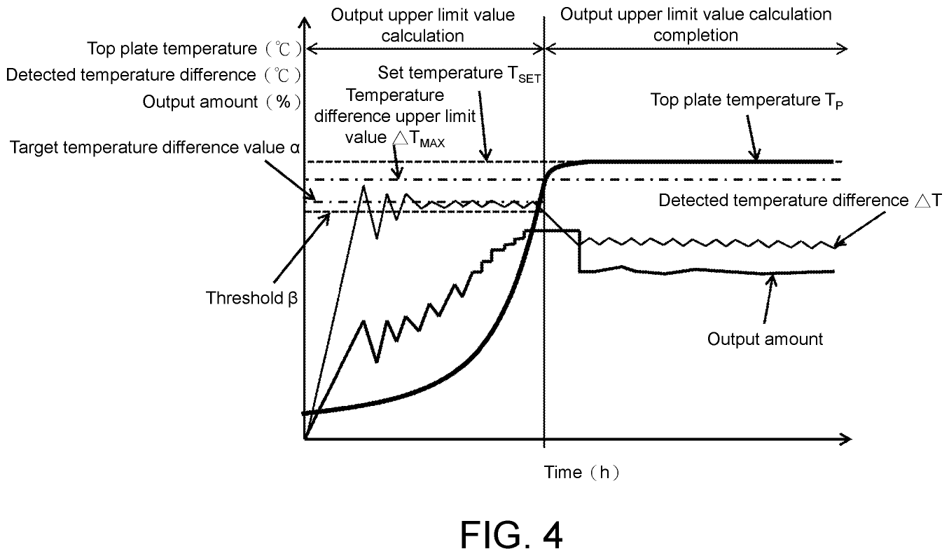

FIG. 5 is a graph illustrating a time series relationship between a set temperature and a detected temperature of a top plate in a modified embodiment.

FIG. 6 is a flowchart illustrating an automatic calculation process for a start output amount according to a modified embodiment.

### REFERENCE SIGNS LIST

100 Substrate heating system

W Substrate

2 Top plate

3 Heater

4 Plate temperature detection part

5 Heater temperature detection part

6 Heater control part

### DESCRIPTION OF THE EMBODIMENTS

Hereinafter, an embodiment of a substrate heating system according to the present invention will be described with reference to the drawings.

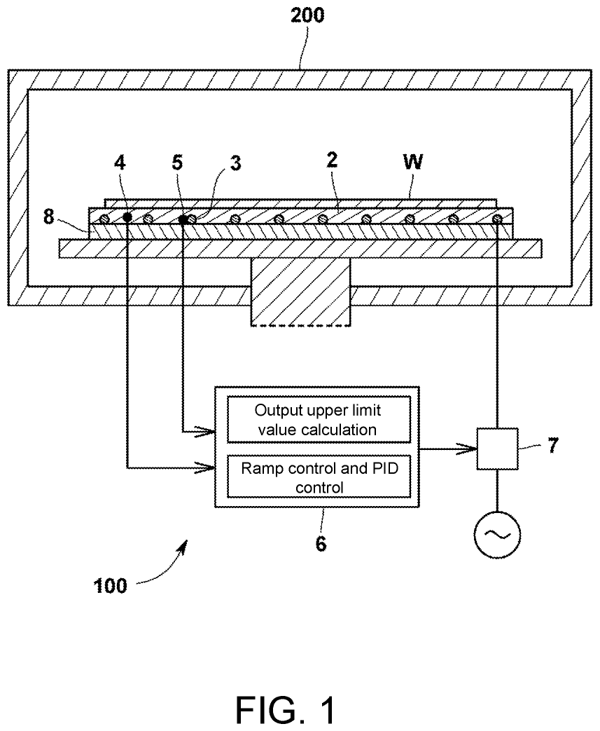

A substrate heating system 100 of the present embodiment is used in a film forming device such as a plasma chemical vapor deposition (CVD) device or an induced couple plasma (ICP) sputtering device, and is specifically provided in a vacuum container 200 and heats a placed substrate W to a prescribed set temperature, as illustrated in FIG. 1.

Specifically, the substrate heating system 100 includes a top plate 2 on which the substrate W is placed, a heater 3 provided on a lower surface of the top plate 2, a plate temperature detection part 4 that detects a temperature T_{P} of the top plate 2, a heater temperature detection part 5 such as a thermocouple that detects a temperature T_{H} of the heater 3, and a heater control part 6 that controls an output of the heater 3 based on the detected temperature T_{H} of the heater 3 and the detected temperature T_{P} of the top plate 2.

In the heater 3 of the present embodiment, an energization amount is adjusted by an energization control device 7 using a power semiconductor device such as a thyristor. Further, the heater 3 is provided to be sandwiched between the top plate 2 and a base plate 8, and the top plate 2 and the base plate 8 constitute a heater plate. Further, the plate temperature detection part 4 is provided in contact with the top plate 2 and, for example, a thermocouple or the like can be used. Further, the heater temperature detection part 5 is provided in contact with the heater 3 and, for example, a thermocouple or the like can be used. The detected temperatures T_{H} and T_{P} of the temperature detection part 4 are input to the heater control part 6.

The heater control part 6 outputs a control signal to the energization control device 7 to control the energization control device 7 to control the output of the heater 3. The heater control part 6 includes a dedicated or general-purpose computer including a CPU, an internal memory, an input and output interface, an AD converter, and the like. Here, the heater control part 6 may be configured using a programmable logic controller (PLC).

Specifically, the heater control part 6 controls the output of the heater 3 such that a detected temperature difference ΔT (=T_{H}−T_{P}) between the detected temperature T_{H} of the heater 3 and the detected temperature T_{P} of the top plate 2 does not exceed a prescribed temperature difference upper limit value ΔT_{MAX}, and performs control such that the detected temperature T_{P} of the top plate 2 is a prescribed set temperature T_{SET}.

Next, an operation of the substrate heating system 100 together with a function of the heater control part 6 will be described.

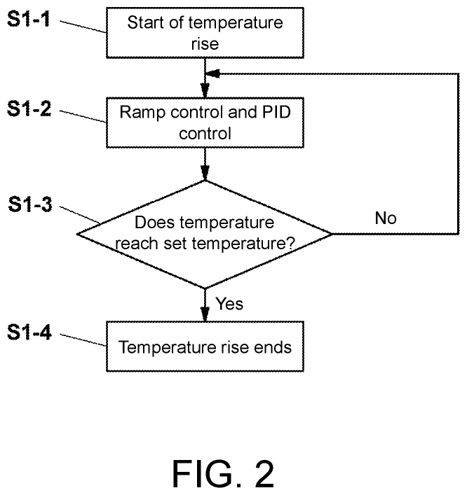

An overview of an operation of the substrate heating system 100 is as illustrated in FIG. 2. That is, when the heater 3 is turned on or when the set temperature T_{SET} is changed to the high temperature side, the heater control part 6 outputs a control signal to the energization control device 7 to start temperature rise of the top plate 2 (S1-1). The set temperature T_{SET} is a temperature that is input by a user and, hereinafter, a case in which the set temperature T_{SET} is 400° C. is considered.

The heater control part 6 performs ramp control and PID control on the output of the heater 3 based on the temperature difference (deviation=T_{SET}−T_{P}) between the set temperature T_{SET} and the detected temperature T_{P} of the top plate 2 to thereby perform control such that the detected temperature T_{P} of the top plate 2 becomes the set temperature T_{SET} (S1-2). Here, in the ramp control, an input is given such that a target value is increased by a prescribed temperature (for example, 1° C.) every unit time (for example, one minute).

Further, the heater control part 6 compares the detected temperature T_{P} of the top plate 2 with the set temperature T_{SET} (S1-3). When the detected temperature T_{P} of the top plate 2 is found to be lower than the set temperature T_{SET} as a result of the comparison, the process returns to S1-2. On the other hand, when the detected temperature T_{P} of the top plate 2 reaches the set temperature TS_{ET}, the temperature rise ends (S1-4).

Next, specific control content of the heater control part 6 will be described.

In S1-2, the heater control part 6 sets an output upper limit value (for example, 750° C.) of the heater 3 based on the detected temperature difference ΔT between the detected temperature T_{H} of the heater 3 and the detected temperature T_{P} of the top plate 2, and performs the ramp control and the PID control on the output of the heater 3 such that the output does not exceed the set output upper limit value.

Therefore, the heater control part 6 determines whether or not to set the output upper limit value after the start of temperature rise (S1-1) (S2-1). Specifically, the heater control part 6 compares the detected temperature T_{P} of the top plate 2 with a threshold temperature (=T_{SET}−10° C.) obtained by subtracting a prescribed temperature (for example, 10° C.) from the set temperature T_{SET}, and sets the output upper limit value when the detected temperature T_{P} of the top plate 2 is lower than the threshold temperature (S2-2). When the detected temperature T_{P} of the top plate 2 is higher than the threshold temperature, the heater control part 6 controls the ramp control and the PID control on the output of the heater 3 such that the detected temperature T_{P} of the top plate 2 becomes the set temperature T_{SET} without setting the output upper limit value (S1-2).

The output upper limit value compares the detected temperature difference ΔT between the detected temperature T_{H} of the heater 3 and the detected temperature T_{P} of the top plate 2 with a prescribed target temperature difference value α (S2-3).

When the detected temperature difference ΔT is smaller than the target temperature difference value α (α>ΔT), the heater control part 6 compares a difference between the target temperature difference value α and the detected temperature difference ΔT (=α−ΔT) with a prescribed threshold β (S2-4). Here, the threshold β can be determined using an actual heating test result of the substrate heating system 100 in consideration of the fact that the detected temperature of the top plate 2 is prevented from suddenly rising due to the process of S2-4.

When the difference (=α−ΔT) between the target temperature difference value α and the detected temperature difference ΔT is larger than the threshold β (α−ΔT>β), the heater control part 6 adds a prescribed value to a current output upper limit value and sets a resultant value as a next output upper limit value (S2-5). Further, when α−ΔT≤β, the process returns to S2-3.

On the other hand, in S2-3, when the detected temperature difference ΔT is larger than the target temperature difference value α (ΔT≤α), the heater control part 6 subtracts a prescribed value from the current output upper limit value and sets a resultant value as the next output upper limit value (S2-6).

The heater control part 6 performs the ramp control and the PID control on the output of the heater 3 based on the set output upper limit value (S1-2).

### Effects of Present Embodiment

According to the substrate heating system 100 of the embodiment configured as described above, since the output of the heater 3 is controlled such that the detected temperature difference ΔT between the detected temperature T_{H} of the heater 3 and the detected temperature T_{P} of the top plate 2 does not exceed the prescribed temperature difference upper limit value T_{MAX}, it is possible to reduce disparity in the thermal expansion between the top plate 2 and the heater 3 and prevent damage to the heater 3. Further, in the present embodiment, the heater control part 6 performs the ramp control and the PID control on the output of the heater such that a temperature rise time can be shortened.

### Modified Embodiment

The present invention is not limited to the above embodiment.

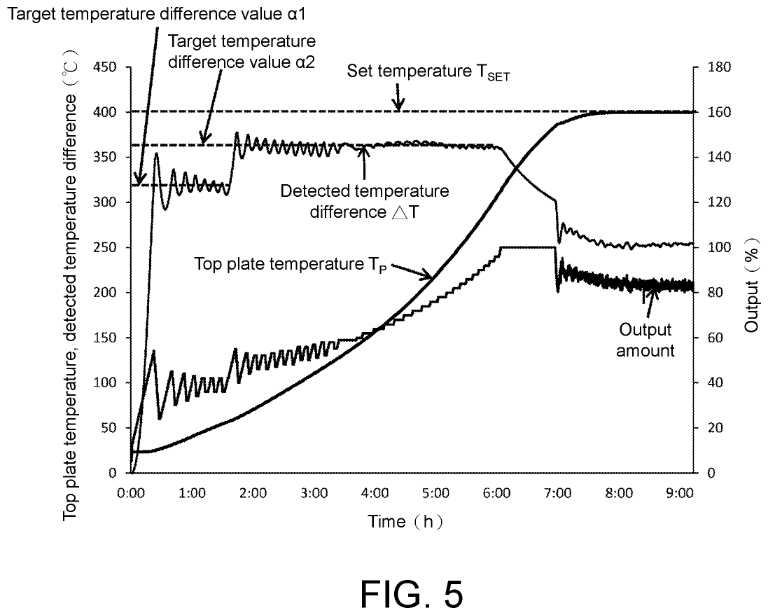

For example, the heater control part 6 may be configured to switch the target temperature difference value α based on the detected temperature T_{P} of the top plate 2 as illustrated in FIG. 5. FIG. 5 illustrates a case in which the target temperature difference value α is increased from α1 to α2 when the detected temperature T_{P} reaches 50° C.

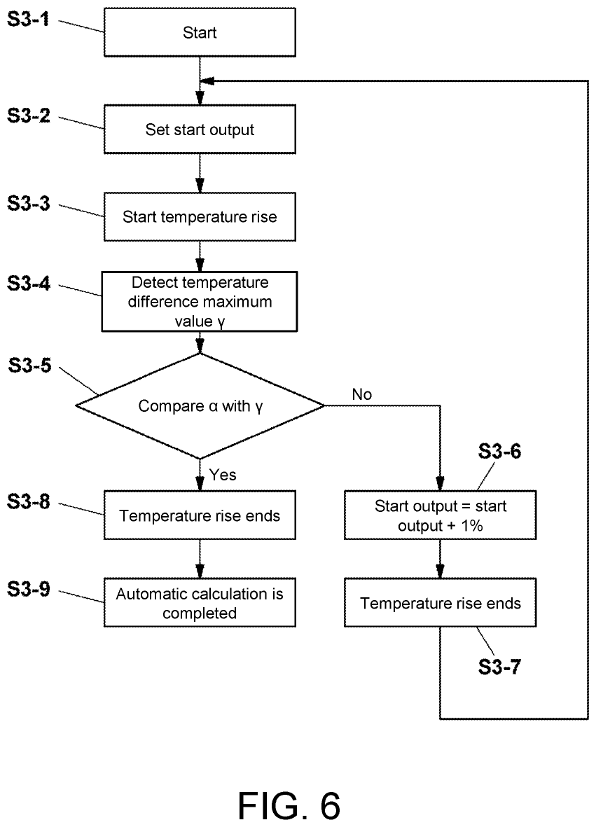

Further, the heater control part 6 may set a start output amount of the heater to 1% in temperature rise of the top plate and perform output control from a start output amount set by the user, or may perform the output control from the start output amount obtained through the automatic calculation, as illustrated in FIG. 6.

Hereinafter, the automatic calculation illustrated in FIG. 6 will be described.

When the calculation of the start output amount is started (S3-1), the heater control part 6 sets the start output in the automatic calculation (S3-2). Here, 1% is set in a first cycle. An updated value is set after the first cycle.

After this setting, the heater control part 6 controls the heater 3 using the set output amount to start the temperature rise (S3-3). Further, the heater control part 6 detects and stores a maximum temperature difference value γ from the start of the temperature rise to a time when the detected temperature difference ΔT becomes constant or decreases (S3-4). In S3-4, it is assumed that γ does not exceed the temperature difference upper limit value ΔT_{MAX}.

The heater control part 6 compares the target temperature difference value α with the maximum temperature difference value γ (S3-5).

When the target temperature difference value α is found to be larger than the maximum temperature difference value γ (α>γ) as a result of this comparison, the heater control part 6 adds a prescribed value (for example, 1%) to a current start output and sets a resultant value as a next start output (S3-6). Thereafter, when the temperature rise ends and the detected temperature of the top plate 2 falls to room temperature (for example, 25° C.), the process is performed again from S3-2 (S3-7).

On the other hand, in S3-5, when the target temperature difference value a is smaller than the maximum temperature difference value γ (α<γ), the temperature rise ends (S3-8). The automatic calculation of the start output amount is completed by performing the above process (S3-9). By automatically calculating the start output amount in this manner, it is possible to list an output amount of the heater all at once immediately after the start of the temperature rise, and to shorten a temperature rise time.

Further, the heater control part may control the output of the heater using a prescribed first output upper limit value when the detected temperature of the heater exceeds a prescribed heater temperature upper limit value.

Further, when the detected temperature difference exceeds the temperature difference upper limit value, the heater control part may control the output of the heater using a prescribed second output upper limit value.

In addition, it is obvious that the present invention is not limited to the above embodiment, and various modifications can be made without departing from the spirit of the present invention.

### INDUSTRIAL APPLICABILITY

According to the present invention, it is possible to reduce disparity in the thermal expansion of the top plate and the heater and to prevent damage to the heater.

1. A substrate heating system comprising:
a top plate on which a substrate is placed;
a heater provided to a lower surface of the top plate;
a plate temperature detection part configured to detect a temperature of the top plate;
a heater temperature detection part configured to detect a temperature of the heater; and
a heater control part configured to control an output of the heater based on a detected temperature of the heater and the detected temperature of the top plate,
wherein the heater control part performs control such that the detected temperature of the top plate is a set temperature which is prescribed while controlling the output of the heater such that a detected temperature difference between the detected temperature of the heater and the detected temperature of the top plate does not exceed a temperature difference upper limit value which is prescribed.

2. The substrate heating system according to claim 1, wherein the heater control part sets an output upper limit value of the heater based on the detected temperature difference.

3. The substrate heating system according to claim 2, wherein the heater control part subtracts a prescribed value from a current output upper limit value and sets a resultant value to a next output upper limit value when the detected temperature difference is larger than a target temperature difference value which is prescribed, and adds a prescribed value to the current output upper limit value and sets a resultant value as the next output upper limit value when the detected temperature difference is smaller than the target temperature difference value which is prescribed.

4. The substrate heating system according to claim 3, wherein, in a case in which the detected temperature difference is smaller than the target temperature difference value which is prescribed, the heater control part adds a prescribed value to the current output upper limit value and sets a resultant value as the next output upper limit value when a difference between the target temperature difference value and the detected temperature difference is larger than a prescribed threshold, and does not change the current output upper limit value when the difference between the target temperature difference value and the detected temperature difference is smaller than the prescribed threshold.

5. The substrate heating system according to claim 3, wherein the heater control part switches the target temperature difference value based on a detected temperature of the top plate.

6. The substrate heating system according to claim 1, wherein the heater control part controls the output of the heater such that the detected temperature difference does not exceed the temperature difference upper limit value when the detected temperature of the top plate is lower than a threshold temperature obtained by subtracting a prescribed temperature from the set temperature, and performs control such that the detected temperature of the top plate is the set temperature when the detected temperature of the top plate is higher than the threshold temperature.

7. The substrate heating system according to claim 1, wherein the heater control part controls the output of the heater using a prescribed first output upper limit value when the detected temperature of the heater exceeds a heater temperature upper limit value which is prescribed.

8. The substrate heating system according to claim 1, wherein the heater control part controls the output of the heater using a prescribed second output upper limit value when the detected temperature difference exceeds the temperature difference upper limit value.

9. A substrate processing device using the substrate heating system according to any one of claim 1.

10. The substrate heating system according to claim 4, wherein the heater control part switches the target temperature difference value based on a detected temperature of the top plate.

11. The substrate heating system according to claim 2, wherein the heater control part controls the output of the heater such that the detected temperature difference does not exceed the temperature difference upper limit value when the detected temperature of the top plate is lower than a threshold temperature obtained by subtracting a prescribed temperature from the set temperature, and performs control such that the detected temperature of the top plate is the set temperature when the detected temperature of the top plate is higher than the threshold temperature.

12. The substrate heating system according to claim 3, wherein the heater control part controls the output of the heater such that the detected temperature difference does not exceed the temperature difference upper limit value when the detected temperature of the top plate is lower than a threshold temperature obtained by subtracting a prescribed temperature from the set temperature, and performs control such that the detected temperature of the top plate is the set temperature when the detected temperature of the top plate is higher than the threshold temperature.

13. The substrate heating system according to claim 4, wherein the heater control part controls the output of the heater such that the detected temperature difference does not exceed the temperature difference upper limit value when the detected temperature of the top plate is lower than a threshold temperature obtained by subtracting a prescribed temperature from the set temperature, and performs control such that the detected temperature of the top plate is the set temperature when the detected temperature of the top plate is higher than the threshold temperature.

14. The substrate heating system according to claim 5, wherein the heater control part controls the output of the heater such that the detected temperature difference does not exceed the temperature difference upper limit value when the detected temperature of the top plate is lower than a threshold temperature obtained by subtracting a prescribed temperature from the set temperature, and performs control such that the detected temperature of the top plate is the set temperature when the detected temperature of the top plate is higher than the threshold temperature.

15. The substrate heating system according to claim 2, wherein the heater control part controls the output of the heater using a prescribed first output upper limit value when the detected temperature of the heater exceeds a heater temperature upper limit value which is prescribed.

16. The substrate heating system according to claim 3, wherein the heater control part controls the output of the heater using a prescribed first output upper limit value when the detected temperature of the heater exceeds a heater temperature upper limit value which is prescribed.

17. The substrate heating system according to claim 4, wherein the heater control part controls the output of the heater using a prescribed first output upper limit value when the detected temperature of the heater exceeds a heater temperature upper limit value which is prescribed.

18. The substrate heating system according to claim 5, wherein the heater control part controls the output of the heater using a prescribed first output upper limit value when the detected temperature of the heater exceeds a heater temperature upper limit value which is prescribed.

19. The substrate heating system according to claim 6, wherein the heater control part controls the output of the heater using a prescribed first output upper limit value when the detected temperature of the heater exceeds a heater temperature upper limit value which is prescribed.

20. The substrate heating system according to claim 2, wherein the heater control part controls the output of the heater using a prescribed second output upper limit value when the detected temperature difference exceeds the temperature difference upper limit value.
